(19) United States
(12) Patent Application Publication
(10) Pub. No.: US 2010/0099047 A1
(43) Pub. Date: Apr. 22, 2010

(54) MANUFACTURE OF DROP DISPENSE APPARATUS

(75) Inventors: Van Nguyen Truskett, Austin, TX (US); Douglas J. Resnick, Leander, TX (US)

Correspondence Address: MOLECULAR IMPRINTS, PO BOX 81536, AUSTIN, TX, 78708-1536, US

(73) Assignee: MOLECULAR IMPRINTS, INC., Austin, TX (US)

(21) Appl. No.: 12/581,243

(22) Filed: Oct. 19, 2009

Related U.S. Application Data
(60) Provisional application No. 61/106,655, filed on Oct. 20, 2008.

(51) Int. Cl. G03F 7/20; B29C 59/02; B44C 1/22

(52) U.S. Cl. 430/320; 264/293; 216/52

(57) ABSTRACT

A drop dispense apparatus may be manufactured utilizing an imprint lithography process. Exemplary methods for manufacturing a drop dispense apparatus are described.

### CROSS-REFERENCE TO RELATED APPLICATION

This application claims the benefit under 35 U.S.C. §119(e)(1) of U.S. Provisional No. 61/106,655, filed Oct. 20, 2008, which is hereby incorporated by reference.

### BACKGROUND INFORMATION

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate, therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Application Publication No. 2004/0065976, U.S. Patent Application Publication No. 2004/0065252, and U.S. Pat. No. 6,936,194, all of which are hereby incorporated by reference herein.

An imprint lithography technique disclosed in each of the aforementioned U.S. patent application publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and the formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### BRIEF DESCRIPTION OF DRAWINGS

So that the present invention may be understood in more detail, a description of embodiments of the invention is provided with reference to the embodiments illustrated in the appended drawings. It is to be noted, however, that the appended drawings illustrate only typical embodiments of the invention, and are therefore not to be considered limiting of the scope.

FIG. 1 illustrates a simplified side view of an embodiment of a lithographic system.

FIG. 2 illustrates a simplified side view of the substrate shown in FIG. 1 having a patterned layer positioned thereon.

FIGS. 3A-3F illustrate a process for manufacturing a nozzle structure of a drop dispense apparatus.

FIGS. 4A-4F illustrate a process for manufacturing a top base of a drop dispense apparatus.

FIG. 5 illustrates a process for bonding together the nozzle structure and the top base.

FIG. 6 illustrates operation of a drop dispense apparatus.

### DETAILED DESCRIPTION

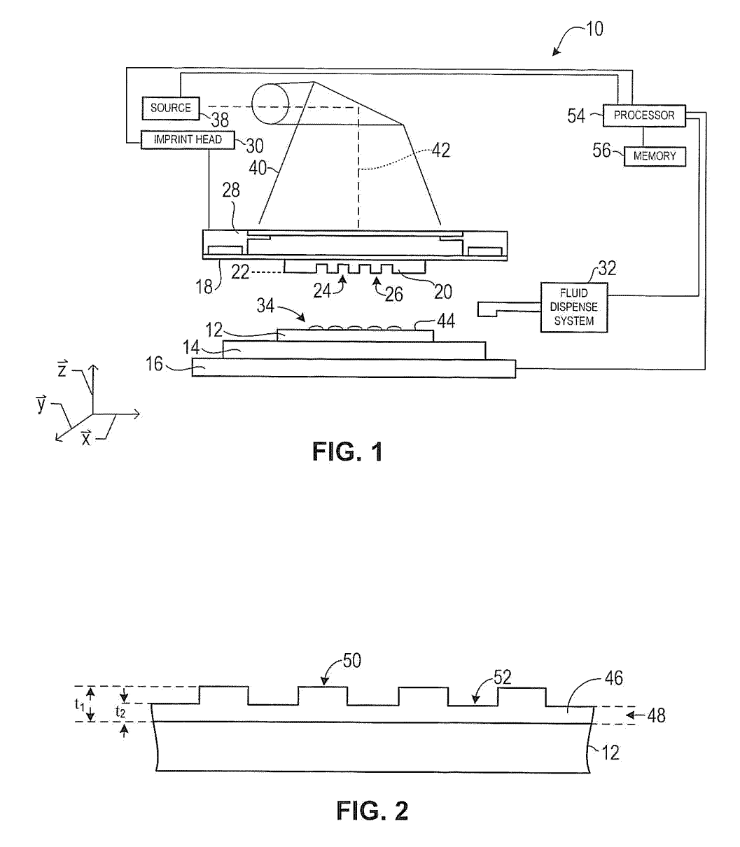

Referring to FIG. 1, illustrated therein is a lithographic system 10 used to form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electromagnetic, and/or the like. Exemplary chucks are described in U.S. Pat. No. 6,873,087, which is hereby incorporated by reference herein.

Substrate 12 and substrate chuck 14 may be further supported by stage 16. Stage 16 may provide motion about the x-, y-, and z-axes. Stage 16, substrate 12, and substrate chuck 14 may also be positioned on a base (not shown).

Spaced-apart from substrate 12 is a template 18. Template 18 generally includes a mesa 20 extending therefrom towards substrate 12, mesa 20 having a patterning surface 22 thereon. Further, mesa 20 may be referred to as mold 20. Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations. Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electromagnetic, and/or other similar chuck types. Exemplary chucks are further described in U.S. Pat. No. 6,873,087, which is hereby incorporated by reference herein. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit polymerizable material 34 on substrate 12. Polymerizable material 34 may be positioned upon substrate 12 using techniques such as drop dispense, spin-coating, dip coating, chemical vapor deposition (CVD), physical vapor deposition (PVD), thin film deposition, thick film deposition, and/or the like. Polymerizable material 34 may be disposed upon substrate 12 before and/or after a desired volume is defined between mold 20 and substrate 12 depending on design considerations. Polymerizable material 34 may comprise a monomer as described in U.S. Pat. No. 7,157,036 and U.S. Patent Application Publication No. 2005/0187339, all of which are hereby incorporated by reference herein.

Referring to FIGS. 1 and 2, system 10 may further comprise an energy source 38 coupled to direct energy 40 along path 42. Imprint head 30 and stage 16 may be configured to position template 18 and substrate 12 in superimposition with path 42. System 10 may be regulated by a processor 54 in communication with stage 16, imprint head 30, fluid dispense system 32, and/or source 38, and may operate on a computer readable program stored in memory 56.

Either imprint head 30, stage 16, or both vary a distance between mold 20 and substrate 12 to define a desired volume therebetween that is filled by polymerizable material 34. For example, imprint head 30 may apply a force to template 18 such that mold 20 contacts polymerizable material 34. After the desired volume is filled with polymerizable material 34, source 38 produces energy 40, e.g., broadband ultraviolet radiation, causing polymerizable material 34 to solidify and/or cross-link conforming to shape of a surface 44 of substrate 12 and patterning surface 22, defining a patterned layer 46 on substrate 12. Patterned layer 46 may comprise a residual layer 48 and a plurality of features shown as protrusions 50 and recessions 52, with protrusions 50 having a thickness t, and residual layer 48 having a thickness t₂.

The above-described system and process may be further implemented in imprint lithography processes and systems referred to in U.S. Pat. No. 6,932,934, U.S. Patent Application Publication No. 2004/0124566, U.S. Patent Application Publication No. 2004/0188381, and U.S. Patent Application Publication No. 2004/0211754, each of which is hereby incorporated by reference herein.

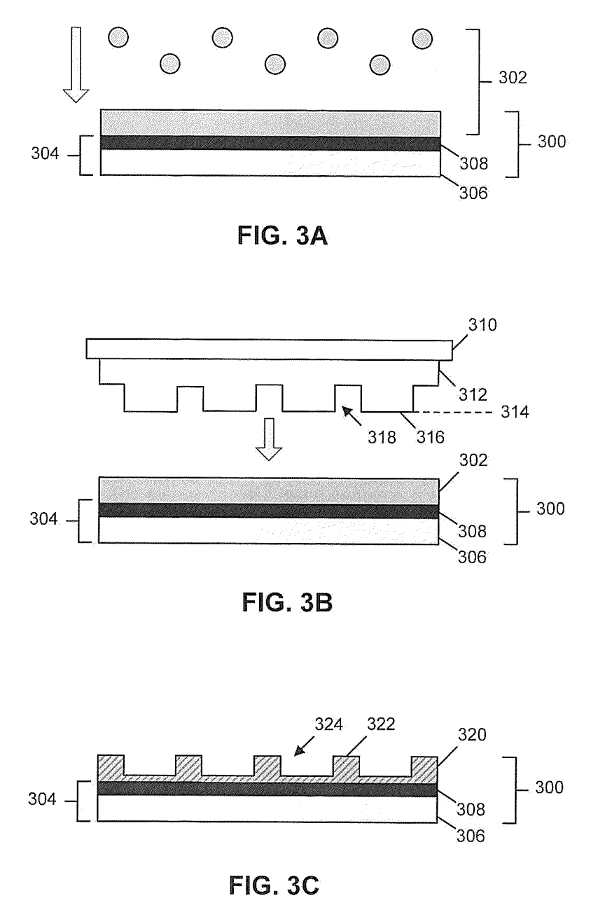

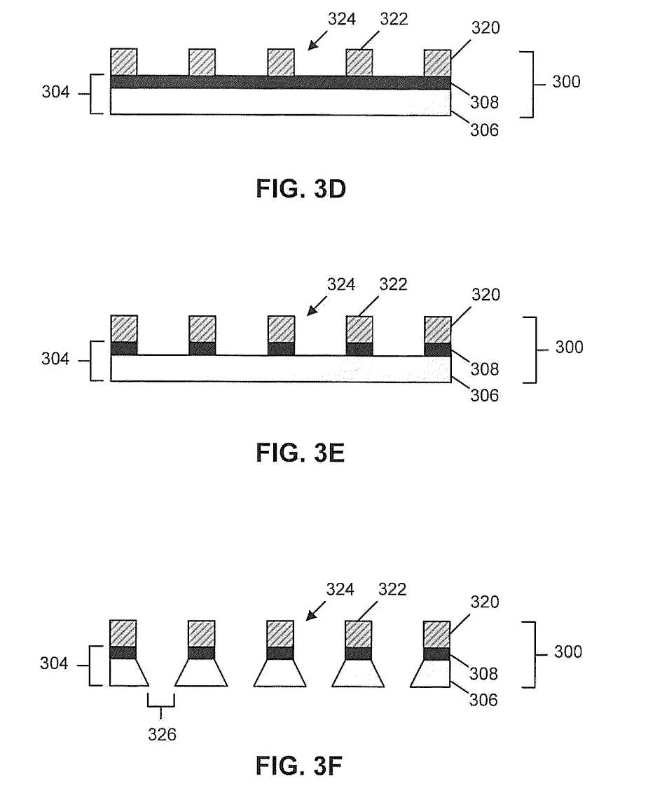

FIGS. 3A-5 illustrate an exemplary method for manufacturing a drop dispense apparatus using imprint lithography as described in relation to FIGS. 1 and 2. Manufacturing the drop dispense apparatus utilizing imprint lithography may provide features of the drop dispense apparatus to be formed with nano-scale accuracy. Additionally, imprint lithography may provide enhanced drop placement accuracy and/or substantial uniformity of nozzles of the drop dispense apparatus. Imprint lithography may provide a cleaner apparatus, i.e., lower particle and ion contamination counts.

Although, FIGS. 3A-5 illustrate a method of manufacturing a drop dispense apparatus using imprint lithography, it should be noted that other methods may be used to manufacture one or more features of the drop dispense apparatus, such as proximity printing, i-line 1× projection lithography, contact printing, i-line reduction lithography, electron beam lithography, 193 nm 4× reduction lithography, deep ultra-violet (DUV) lithography, or a combination thereof.

FIGS. 3A-3F illustrate an exemplary process for manufacturing a nozzle structure 300 of a drop dispense apparatus. The fluid dispense system 32 of FIG. 1 may include a drop dispense apparatus comprising the nozzle structure 300. In some embodiments, the lithographic system 10 and processes of FIGS. 1 and 2 may be used to manufacture the nozzle structure 300. In FIG. 3A, formable material 302 may be dispensed on a substrate 304. Formable material 302 may be a polymerizable material, such as the polymerizable material 34 of FIG. 1. Substrate 304 comprises a substrate layer 306 (e.g., Silicon layer) with a metal layer 308 thereon.

In FIG. 3B, an imprint template 310 may be positioned in contact with formable material 302. The imprint template 310 may include a mold 312 with a patterning surface 314. The patterning surface 314 may include features (e.g., a protrusions 316 and recesses 318). Although a particular patterning surface 314 is illustrated, in FIG. 3B, the patterning surface 314 is not limited to the configuration shown in FIG. 3B. For example, although FIG. 3B shows a two-dimensional view of the patterning surface 314, the patterning surface 314 may comprise a three-dimensional surface having several rows of recesses and protrusions. In some embodiments, the arrangement of recesses 318 and protrusions 316 in one or more rows of the patterning surface 314 may be staggered with respect to the recesses and protrusions of adjacent rows. Alternatively, protrusions 316 and recesses 318 may be arranged sporadically depending on design considerations.

In FIG. 3C, the formable material 302 is cured to produce a patterned layer 320. For example, energy, such as broadband ultraviolet radiation, may be applied to the formable material 302. The patterned layer 320 includes a number of protrusions 322 and recesses 324 based on the patterning surface 314 applied to the formable material 302.

In FIG. 3D, a first etch process may be performed to etch the residual layer lying in the recesses 324 between the protrusions 322 in the pattern of the patterned layer 320. In FIG. 3E, a second etch process is performed to etch away the metal layer 308 in the previously etched recesses 324 between the protrusions 322 in the pattern of the patterned layer 320. Then, in FIG. 3F, a third etch process is performed to etch away substrate layer 306 through the aforementioned recesses 324 creating nozzles 326 of the nozzle structure 300. In one embodiment, nozzles 326 may be tapered from top to bottom, as shown in FIG. 3F. In another embodiment, the nozzles 326 may have a different shape, such as cylindrical, rectangular, triangular, hexagonal, and/or any fanciful shape. A diameter of the nozzles 326 may be less than 20 microns. In addition, a pitch of the nozzles 326 may be less than 200 microns.

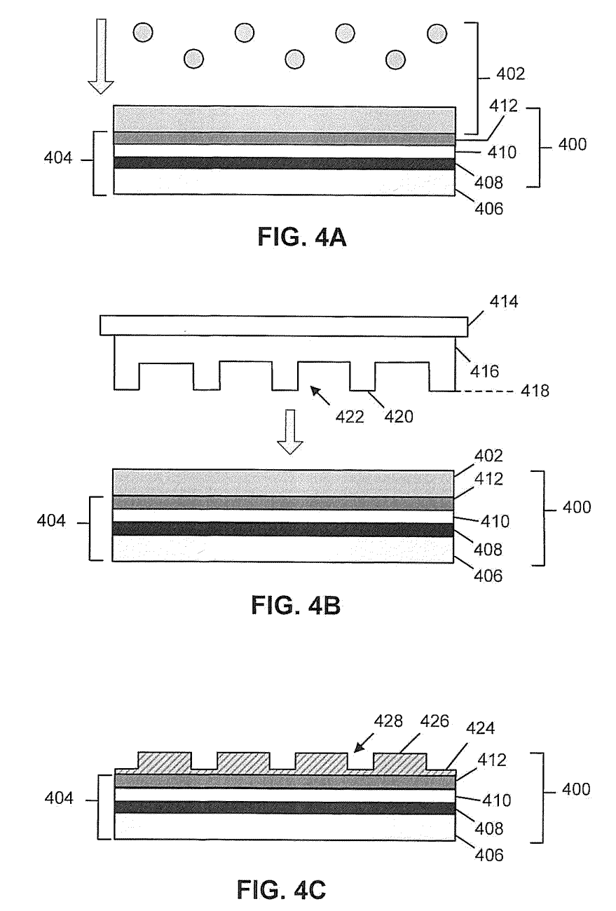

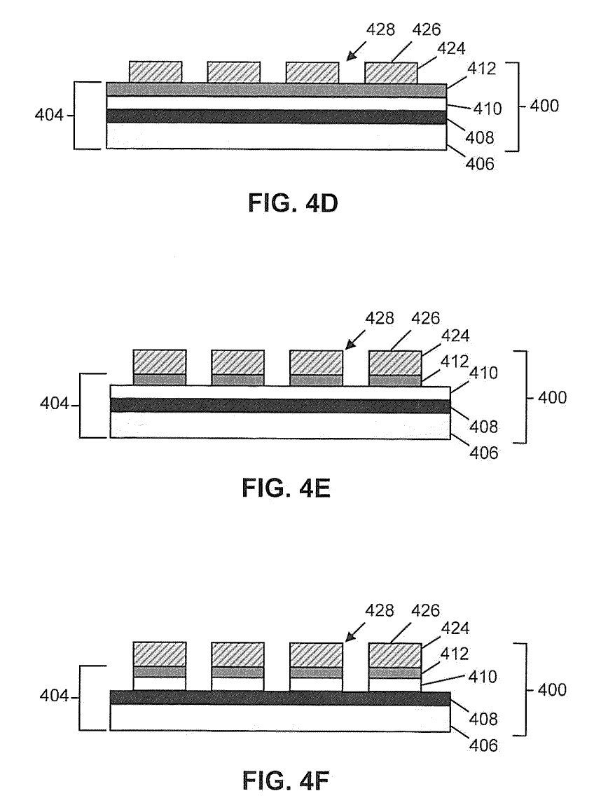

FIGS. 4A-4F illustrate a process for manufacturing a top base 400 of a drop dispense apparatus. The top base 400 may include a number of actuators utilized to dispense fluid via a fluid output device, such as the nozzle structure 300 of FIGS. 3A-3F. The fluid dispense system 32 of FIG. 1 may include a drop dispense apparatus comprising the top base 400. In some embodiments, the lithographic system 10 of FIG. 1 may be used to manufacture the top base 400.

Referring to FIG. 4A, formable material 402 may be dispensed on a substrate 404. The formable material 402 may be a polymerizable material, such as the polymerizable material 34 of FIG. 1. The substrate 404 includes a substrate layer 406 (e.g., Si layer), a first metal layer 408 thereon, a lead zirconate titanate (PZT) layer 410, and a second metal layer 412 thereon. In a particular embodiment, the substrate 404 is formed by depositing a stacked layer of metal, PZT and metal. The PZT layer 410 may also be comprised of a derivative of PZT. In some embodiments, the substrate 404 may include a hardmask layer (not shown) between the formable material 402 and the second metal layer 412. The hardmask layer may be comprised of silicon dioxide, silicon nitride, and/or the like.

Referring to FIG. 4B, a template 414 is applied to the formable material 402 of the top base 400. The template 414 may include a mold 416 with a patterning surface 418. The patterning surface 418 may include features (e.g., protrusions 420 and recesses 422. Although a particular patterning surface 418 is illustrated in FIG. 4B, the patterning surface 418 is not limited to the configuration shown in FIG. 4B. For example, although FIG. 4B shows a two-dimensional view of the patterning surface 418, the patterning surface 418 may comprise a three-dimensional surface having several rows of recesses and protrusions. In some embodiments, the arrangement of recesses 422 and protrusions 420 in one or more rows of the patterning surface 418 may be staggered with respect to the recesses and protrusions of adjacent rows. In a particular illustrative embodiment, the arrangement of protrusions 420 and recesses 422 may be complementary to the protrusions 316 and recesses 318 of the patterning surface 314 of FIG. 3B. For example, the protrusions 420 may be aligned with the recesses 318 and the recesses 422 may be aligned with the protrusions 316. Alternatively, protrusions 420 and recesses 318 may be arranged sporadically depending on design considerations.

Referring to FIG. 4C, the formable material 402 may be cured to provide patterned layer 424. For example, the formable material 402 may be cured by applying ultraviolet radiation or another energy source to the formable material 402. The patterned layer 424 may include a number of protrusions 426 and recesses 428 based on the patterning surface 418 applied to the formable material 402.

Referring to FIG. 4D, an etch process may be performed etching the residual layer lying in the recesses 428 between the protrusions 426 in the pattern of the patterned layer 424. In FIG. 4E, an etch process may be performed etching away the second metal layer 412 in the recesses 428. In FIG. 4F, an etch process may be performed etching away the PZT layer 410 in the previously etched recesses 428 between the protrusions 426 in the pattern of the patterned layer 424, resulting in the top base 400.

Depending on the composition of the patterned layer 320, 424, the etch process for any of the etching steps shown in FIGS. 3D-3F and 4D-4F may be a wet etch (e.g., KOH solution) or a dry etch (e.g., deep reactive ion etching, sputter etching, or vapor phase etching), or any equivalent thereof. Gas chemistries utilized with reactive ion etching may include one or more of Cl₂/Ar, SiCl/Cl₂/Ar, SF₆/Ar, and CF₄/CHF₃/Ar. The PZT layer 410 may also be etched via a wet etching process utilizing dilute HF.

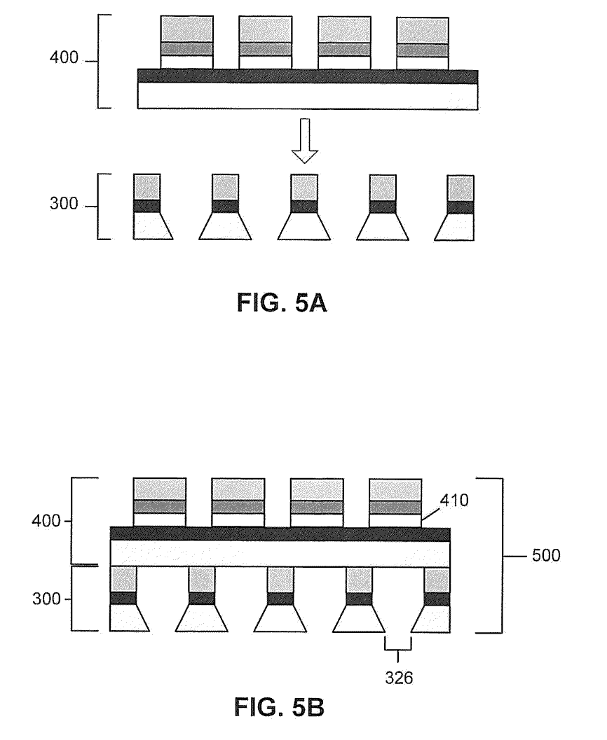

Referring to FIG. 5A, the top base 400 may be bonded to the nozzle structure 300 using bonding techniques, such as direct bonding, anodic bonding, or adhesive bonding, but is not limited to these. FIG. 5B illustrates a drop dispense apparatus 500 produced by the bonding of the top base 400 with the nozzle structure 300. In the illustrated embodiment shown in FIG. 5B, an isolated PZT actuator region 410 is formed over the fluid chamber of each nozzle 326.

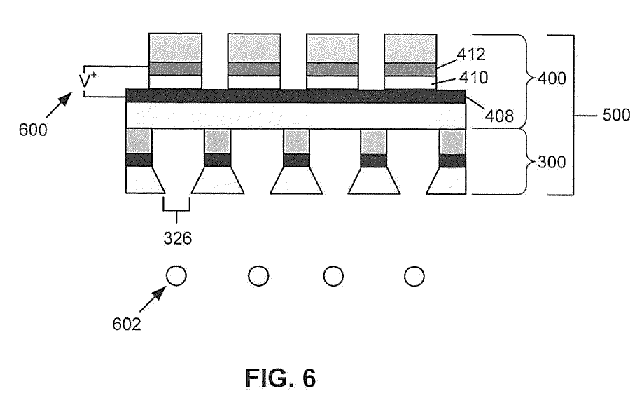

FIG. 6 illustrates an operation of the drop dispense apparatus 500. In one embodiment, electrical components (not shown) of the drop dispense apparatus 500 may apply a voltage 600 to the metal layers 408 and 412 above and below the PZT layer 410. In response to the applied voltage, drops 602 of fluid stored in a fluid chamber (not shown) may be ejected from one or more nozzles 326 of the drop dispense apparatus 500. For example, applying a voltage to the metal layers 408, 412 may cause the actuators 410 of the top base 400 to force fluid through one or more of the nozzles 326. In some embodiments, the fluid may be routed through the top base 400 and/or through the nozzle structure 300 to fill the nozzles 326.

The fluid chamber and other supporting structures of the drop dispense apparatus 500 may be formed utilizing an imprint lithography process, a photo lithography process, one or more complementary metal oxide semiconductor (CMOS) etch processes, or a combination thereof. The drops 602 may be comprised of any industrial fluid, such as biofluids or the formable material 34 of FIG. 1, 302 of FIG. 3A, or 402 of FIG. 4. The volume of the drops 602 may be less than 3 picoliters.

What is claimed is:

1. A method of manufacturing a drop dispense apparatus, the method comprising:
forming at least one nozzle of the drop dispense apparatus from a template by utilizing an imprint lithography process.

2. The method of claim 1, further comprising applying a polymerizable material to a substrate.

3. The method of claim 2, further comprising applying a patterning surface of the template to the polymerizable material.

4. The method of claim 3, further comprising curing the polymerizable material after the patterning surface is applied to produce a patterned layer.

5. The method of claim 4, wherein a particular nozzle of the drop dispense apparatus is formed by etching the patterned layer.

6. The method of claim 1, wherein a particular nozzle of the drop dispense apparatus is formed by etching a metal layer of a substrate.

7. The method of claim 1, wherein a particular nozzle of the drop dispense apparatus is formed by etching a silicon layer of a substrate.

8. The method of claim 1, wherein a particular nozzle is tapered from top to bottom.

9. A method of manufacturing a drop dispense apparatus, the method comprising:
forming a top base of the drop dispense apparatus from a template by utilizing an imprint lithography process, the top base including at least one actuator.

10. The method of claim 9, further comprising applying a polymerizable material to a substrate and applying a patterning surface of the template to the polymerizable material.

11. The method of claim 10, further comprising curing the polymerizable material by applying ultraviolet radiation to produce a patterned layer.

12. The method of claim 11, wherein a particular actuator of the top base is formed by etching the patterned layer.

13. The method of claim 9, further comprising depositing a lead zirconate titanate film on a first metal layer of a substrate.

14. The method of claim 13, further comprising depositing a second metal layer on the lead zirconate titanate film.

15. The method of claim 13, wherein a particular actuator of the top base is formed by etching the lead zirconate titanate film.

16. The method of claim 14, wherein a particular actuator of the top base is formed by etching the second metal layer.

17. A method of manufacturing a drop dispense apparatus, the method comprising:
bonding a top base including a plurality of actuators with a nozzle structure including a plurality of nozzles, at least one of the plurality of nozzles is aligned with a respective actuator.

18. The method of claim 17, further comprising ejecting drops of fluid from one or more nozzles of the nozzle structure in response to an applied voltage.

19. The method of claim 17, wherein a fluid chamber of the drop dispense apparatus is formed utilizing an imprint lithography process, a photolithography process, one or more etch processes, or a combination thereof.

20. The method of claim 17, wherein the top base and the nozzle structure are formed from an imprint lithography process.
